(19) United States
(12) Patent Application Publication
(10) Pub. No.: US 2018/0212013 A1
(43) Pub. Date: Jul. 26, 2018

(54) DOUBLE-SIDED OLED DISPLAY DEVICE

(71) Applicant: WUHAN CHINA STAR OPTOELECTRONICS TECHNOLOGY CO., LTD., Wuhan (CN)

(72) Inventors: Haiyan SUN, Wuhan (CN); Yuejun TANG, Wuhan (CN)

(73) Assignee: WUHAN CHINA STAR OPTOELECTRONICS TECHNOLOGY CO., LTD., Wuhan (CN)

(21) Appl. No.: 15/321,742

(22) PCT Filed: Oct. 13, 2016
(86) PCT No.: PCT/CN2016/101954

§ 371 Date: Dec. 22, 2016

(30) Foreign Application Priority Data
Aug. 31, 2016 (CN) 201610784866.5

(51) Int. Cl. H01L 27/32; H01L 51/52

(52) U.S. Cl. CPC H01L 27/3267; H01L 51/524; H01L 51/5253

(57) ABSTRACT

A double-sided OLED display device is provided. The double-sided OLED display device has a first display element, a second display element, a first sealing layer, and a second sealing layer. The first display element is disposed on an upper side of the second display element, and the light-emitting direction of the first display element and the second display element are opposite. The first sealing layer is disposed on an upper side of the first display element, and the second sealing layer is disposed on a lower side of the second display element. Thus, the first display element and the second display element are sealed and packaged by the first sealing layer and the second sealing layer.

### FIELD OF THE INVENTION

The present invention relates to a double-sided OLED display device, and more particularly to a double-sided OLED display device with a simple structure which is moisture proof.

### BACKGROUND OF THE INVENTION

With technological development, double-sided display devices are required by more and more users, in particular double-sided OLED display devices.

A package structure of a common double-sided OLED display device is to adopt packaging films to package two display panels, respectively. However, this package structure is too complex, and is disadvantageous for increasing productivity. Furthermore, the double-sided OLED display device is usually used under variable environments and harsh conditions, for example an outside display board or advertising board. Thus, the inside of the double-sided OLED display device is easily invaded by moisture which damages electric elements therein, so that it causes the lifetime of the double-sided OLED display device to be reduced.

Hence, it is necessary to provide a double-sided OLED display device so as to solve the problems existing in the conventional technologies.

### SUMMARY OF THE INVENTION

The object of the present invention is to provide double-sided OLED display device with a simple structure which is moisture proof to solve a technical problem of a conventional double-sided OLED display device that has a package structure which is too complex and the moisture proofing thereof is worse.

The present invention provides a double-sided OLED display device, which comprises: a first display element, a second display element, a first sealing layer, and a second sealing layer, wherein the first display element is disposed on an upper side of the second display element, and a light-emitting direction of the first display element is opposite to that of the second display element; the first sealing layer is disposed on an upper side of the first display element, and the second sealing layer is disposed on a lower side of the second display element;
wherein the first display element and the second display element are combined into one piece which is entirely sealed and packaged by the first sealing layer and the second sealing layer; and the first sealing layer and the second sealing layer are sealed and fixed by a sealing portion;
wherein the sealing portion is a sealing plastic frame or a sealant layer;
wherein each of the first light-emitting portion and the second light-emitting portion includes a light-emitting layer, a positive electrode, an organic functional layer, and a negative electrode; and
wherein the light-emitting layer is disposed between the positive electrode and the organic functional layer, and the organic functional layer is disposed between the light-emitting layer and the negative electrode.

In the double-sided OLED display device according to the present invention, each of the first display element and the second display element is a top light-emitting type display element, while the first display element and the second display element are connected to each other in a back-to-back manner;
wherein the first display element includes a first substrate and a first light-emitting portion formed on the first substrate; and the second display element includes a second substrate and a second light-emitting portion formed on the second substrate; and
wherein a bottom of the first substrate and a bottom of the second substrate are fixedly connected by a glue layer; and a quadrilateral edge portion of the first sealing layer is sealed and fixed to a quadrilateral edge portion of the second sealing layer by the sealing portion.

In the double-sided OLED display device according to the present invention, each of the first display element and the second display element is a top light-emitting type display element, while the first display element and the second display element are connected to each other in a back-to-back manner;
wherein the first display element includes a first substrate and a first light-emitting portion formed on the first substrate; and the second display element includes a second substrate and a second light-emitting portion formed on the second substrate; and
wherein a quadrilateral edge portion of the first substrate is completely or partially inserted into the sealing portion; a quadrilateral edge portion of the second substrate is completely or partially inserted into the sealing portion; the first substrate and the second substrate are fixedly connected by the sealing portion; and a quadrilateral edge portion of the first sealing layer is sealed and fixed to a quadrilateral edge portion of the second sealing layer by the sealing portion.

In the double-sided OLED display device according to the present invention, each of the first display element and the second display element is a top light-emitting type display elements, while the first display element and the second display element are connected to each other in a back-to-back manner;
wherein the first display element and the second display element share a substrate; the first display element further includes a first light-emitting portion formed on the substrate; and the second display element further includes a second light-emitting portion formed on the substrate; and
wherein the first light-emitting portion is disposed on a top surface of the substrate, and the second light-emitting portion is disposed on a bottom surface of the substrate; and a quadrilateral edge portion of the first sealing layer is sealed and fixed to a quadrilateral edge portion of the second sealing layer by the sealing portion.

In the double-sided OLED display device according to the present invention, the substrate is inserted into the sealing portion.

In the double-sided OLED display device according to the present invention, the first display element is a bottom light-emitting type display element, and the second display element is a top light-emitting type display element; and the first display element and the second display element face an identical direction;
wherein the first display element includes a first substrate and a first light-emitting portion formed on the first substrate; and the second display element includes a second substrate and a second light-emitting portion formed on the second substrate; and
wherein the first sealing layer is the first substrate; a quadrilateral edge portion of the second substrate are partially inserted into the sealing portion, and the second substrate is fixedly connected to the first substrate by the sealing portion; and a quadrilateral edge portion of the first sealing layer is sealed and fixed to a quadrilateral edge portion of the second sealing layer by the sealing portion.

In the double-sided OLED display device according to the present invention, each of the first display element and the second display element is a bottom light-emitting type display elements, while the first display element and the second display element are opposite to each other in a face-to-face manner;
wherein the first display element includes a first substrate and a first light-emitting portion formed on the first substrate; and the second display element includes a second substrate and a second light-emitting portion formed on the second substrate; and
wherein the first sealing layer is the first substrate, and the second sealing layer is the second substrate; and a quadrilateral edge portion of the first substrate is sealed and fixed to a quadrilateral edge portion of the second substrate by the sealing portion.

In the double-sided OLED display device according to the present invention, each of an outer surface of the first light-emitting portion and an outer surface of the second light-emitting portion is covered with a thin-film sealing layer.

The present invention provides a double-sided OLED display device, which comprises: a first display element, a second display element, a first sealing layer, and a second sealing layer, wherein the first display element is disposed on an upper side of the second display element, and a light-emitting direction of the first display element is opposite to that of the second display element; the first sealing layer is disposed on an upper side of the first display element, and the second sealing layer is disposed on a lower side of the second display element;
wherein the first display element and the second display element are combined into one piece which is entirely sealed and packaged by the first sealing layer and the second sealing layer; and the first sealing layer and the second sealing layer are sealed and fixed by a sealing portion.

In the double-sided OLED display device according to the present invention, each of the first display element and the second display element is a top light-emitting type display element, while the first display element and the second display element are connected to each other in a back-to-back manner;
wherein the first display element includes a first substrate and a first light-emitting portion formed on the first substrate; and the second display element includes a second substrate and a second light-emitting portion formed on the second substrate; and
wherein a bottom of the first substrate and a bottom of the second substrate are fixedly connected by a glue layer; and a quadrilateral edge portion of the first sealing layer is sealed and fixed to a quadrilateral edge portion of the second sealing layer by the sealing portion.

In the double-sided OLED display device according to the present invention, each of the first display element and the second display element is a top light-emitting type display element, while the first display element and the second display element are connected to each other in a back-to-back manner;
wherein the first display element includes a first substrate and a first light-emitting portion formed on the first substrate; and the second display element includes a second substrate and a second light-emitting portion formed on the second substrate; and
wherein a quadrilateral edge portion of the first substrate is completely or partially inserted into the sealing portion; a quadrilateral edge portion of the second substrate is completely or partially inserted into the sealing portion; the first substrate and the second substrate are fixedly connected by the sealing portion; and a quadrilateral edge portion of the first sealing layer is sealed and fixed to a quadrilateral edge portion of the second sealing layer by the sealing portion.

In the double-sided OLED display device according to the present invention, each of the first display element and the second display element is a top light-emitting type display elements, while the first display element and the second display element are connected to each other in a back-to-back manner;
wherein the first display element and the second display element share a substrate; the first display element further includes a first light-emitting portion formed on the substrate; and the second display element further includes a second light-emitting portion formed on the substrate; and
wherein the first light-emitting portion is disposed on a top surface of the substrate, and the second light-emitting portion is disposed on a bottom surface of the substrate; and a quadrilateral edge portion of the first sealing layer is sealed and fixed to a quadrilateral edge portion of the second sealing layer by the sealing portion.

In the double-sided OLED display device according to the present invention, the substrate is inserted into the sealing portion.

In the double-sided OLED display device according to the present invention, the first display element is a bottom light-emitting type display element, and the second display element is a top light-emitting type display element; and the first display element and the second display element face an identical direction;
wherein the first display element includes a first substrate and a first light-emitting portion formed on the first substrate; and the second display element includes a second substrate and a second light-emitting portion formed on the second substrate; and
wherein the first sealing layer is the first substrate; a quadrilateral edge portion of the second substrate is partially inserted into the sealing portion, and the second substrate is fixedly connected to the first substrate by the sealing portion; and a quadrilateral edge portion of the first sealing layer is sealed and fixed to a quadrilateral edge portion of the second sealing layer by the sealing portion.

In the double-sided OLED display device according to the present invention, each of the first display element and the second display element is a bottom light-emitting type display elements, while the first display element and the second display element are opposite to each other in a face-to-face manner;
wherein the first display element includes a first substrate and a first light-emitting portion formed on the first substrate; and the second display element includes a second substrate and a second light-emitting portion formed on the second substrate; and
wherein the first sealing layer is the first substrate, and the second sealing layer is the second substrate; and a quadrilateral edge portion of the first substrate is sealed and fixed to a quadrilateral edge portion of the second substrate by the sealing portion.

In the double-sided OLED display device according to the present invention, each of an outer surface of the first light-emitting portion and an outer surface of the second light-emitting portion is covered with a thin-film sealing layer.

In the double-sided OLED display device according to the present invention, the sealing portion is a sealing plastic frame or a sealant layer.

In the double-sided OLED display device according to the present invention, each of the first light-emitting portion and the second light-emitting portion includes a light-emitting layer, a positive electrode, an organic functional layer, and a negative electrode; and
wherein the light-emitting layer is disposed between the positive electrode and the organic functional layer, and the organic functional layer is disposed between the light-emitting layer and the negative electrode.

Compared with the conventional double-sided OLED display device, in the double-sided OLED display device according to the present invention, by disposing the first sealing layer and the second sealing layer, the double-sided OLED display device is entirely sealed and packaged, so that the package structure of the preferred embodiment is simple. Additionally, in the double-sided OLED display device according to the present invention, when the sealing layers are packaged, a sealing property of the package structure is improved by disposing the sealing portion, so that the moisture proofing of the present invention is increased, and the lifetime of the preferred embodiment is lengthened. Therefore, it can solve the technical problem of the conventional double-sided OLED display device that has a package structure which is too complex and the moisture proofing thereof is worse.

The above-mention contents of the present invention can be best understood by referring to the following detailed description of the preferred embodiments and the accompanying drawings.

### DESCRIPTION OF THE DRAWINGS

FIG. 1 is a schematic structural view of a double-sided OLED display device according to a first preferred embodiment of the present invention;

FIG. 2 is a schematic structural view of a double-sided OLED display device according to a second preferred embodiment of the present invention;

FIG. 3 is a schematic structural view of a double-sided OLED display device according to a third preferred embodiment of the present invention;

FIG. 4 is a schematic structural view of a double-sided OLED display device according to a fourth preferred embodiment of the present invention;

FIG. 5 is a schematic structural view of a double-sided OLED display device according to a fifth preferred embodiment of the present invention;

FIG. 6 is a schematic structural view of a double-sided OLED display device according to a sixth preferred embodiment of the present invention;

FIG. 7 is a schematic structural view of a double-sided OLED display device according to a seventh preferred embodiment of the present invention; and

FIG. 8 is a schematic structural view of a double-sided OLED display device according to an eighth preferred embodiment of the present invention.

### DETAILED DESCRIPTION OF THE PREFERRED EMBODIMENTS

The foregoing objects, features, and advantages adopted by the present invention can be best understood by referring to the following detailed description of the preferred embodiments and the accompanying drawings. Furthermore, the directional terms described in the present invention, such as upper, lower, front, rear, left, right, inside, outer, side, etc., are only directions with reference to the accompanying drawings, so that the used directional terms are used to describe and understand the present invention, but the present invention is not limited thereto.

In the drawings, units with similar structures use the same numerals.

Refer now to FIG. 1, which is a schematic structural view of a double-sided OLED display device according to a first preferred embodiment of the present invention. The double-sided OLED display device 10 comprises a first display element 11, a second display element 12, a first sealing layer 13, and a second sealing layer 14.

The first display element 11 is disposed on an upper side of the second display element 12, and a light-emitting direction of the first display element 11 is opposite to that of the second display element 12; the first sealing layer 13 is disposed on an upper side of the first display element 11, and the second sealing layer 14 is disposed on a lower side of the second display element 12; the first display element 11 includes a first substrate 111 and a first light-emitting portion 112 formed on the first substrate 111; and the second display element 12 includes a second substrate 121 and a second light-emitting portion 122 formed on the second substrate 121.

The first display element 11 and the second display element 12 are both top light-emitting type display elements, wherein the first display element 11 and the second display element 12 are connected to each other in a back-to-back manner.

A bottom of the first substrate 111 and a bottom of the second substrate 121 are fixedly connected by a glue layer 16. The first display element 11 and the second display element 12 are combined into one piece which is entirely sealed and packaged by the first sealing layer 13 and the second sealing layer 14. Additionally, by a sealing portion 15, a quadrilateral edge portion of the first sealing layer 13 and a quadrilateral edge portion of the second sealing layer 14 are sealed and fixed.

Each of the first light-emitting portion 112 and the second light-emitting portion 122 includes a light-emitting layer, a positive electrode, a first organic functional layer, and a negative electrode. The light-emitting layer is disposed between the positive electrode and the first organic functional layer. The first organic functional layer is disposed between the light-emitting layer and the negative electrode, and the negative electrode is connected to an auxiliary electrode. The first organic functional layer can included at least one layer of a hole blocking layer, an electron transport layer, or an electron injection layer.

Each of the first light-emitting portion 112 and the second light-emitting portion 122 can further include a second organic functional layer disposed between the light-emitting layer and the negative electrode, and the second organic functional layer can included at least one layer of a hole an injection layer, a hole transport layer, or an electron blocking layer.

It can be understood that the double-sided OLED display device is more used outside, usually suffering bad weather, such as storms, so that the double-sided OLED display device is easily contacted by an external object. Therefore, for improving the strength of a package structure of this preferred embodiment, each of the first sealing layer 13 and the second sealing layer 14 is preferably an outer cover with stronger structure. For further improving the strength of the package structure of this preferred embodiment, the sealing portion 15 can be a sealant layer or a sealing plastic frame.

The entire packaging operation can be: firstly, putting a packaging surface of a first sealing layer 13 upward; next, adhering a bottom of a first substrate 111 of a first display element 11 and a bottom of a second substrate 121 of a second display element 12 by a glue layer 16, and putting the first display element 11 and the second display element 12 on the first sealing layer 13; next, coating a sealant layer on the first sealing layer 13; finally, covering a second sealing layer 14 on the first display element 11 and the second display element 12, and curing the sealant layer, so that the corresponding entire packaging operation is finished.

An advantage of this preferred embodiment is that: in the preferred embodiment, by disposing the first sealing layer 13 and the second sealing layer 14, the first display element 11 and the second display element 12 are entirely sealed and packaged, thus the package structure of the preferred embodiment is simple. Additionally, in the preferred embodiment, when the first sealing layer 13 and the second sealing layer 14 are packaged, a sealing property of the package structure is improved by disposing the sealing portion 15, so that the moisture proofing is improved, and the lifetime of the preferred embodiment is lengthened.

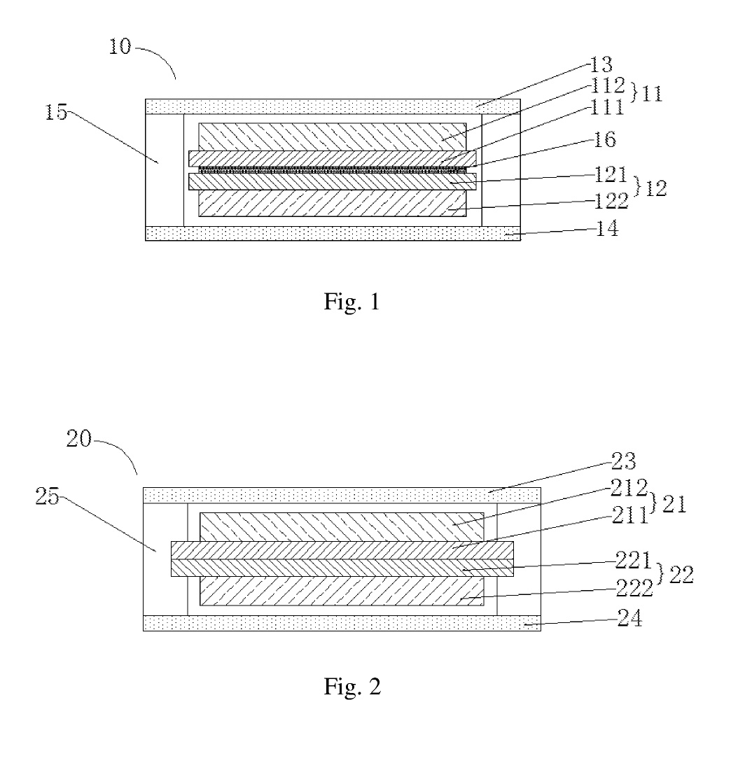

Refer now to FIG. 2, which is a schematic structural view of a double-sided OLED display device according to a second preferred embodiment of the present invention. The double-sided OLED display device 20 comprises a first display element 21, a second display element 22, a first sealing layer 23, and a second sealing layer 24.

The first display element 21 is disposed on an upper side of the second display element 22, and a light-emitting direction of the first display element 21 is opposite to that of the second display element 22; the first sealing layer 23 is disposed on an upper side of the first display element 21, and the second sealing layer 24 is disposed on a lower side of the second display element 22; the first display element 21 includes a first substrate 211 and a first light-emitting portion 212 formed on the first substrate 211; and the second display element 22 includes a second substrate 221 and a second light-emitting portion 222 formed on the second substrate 221.

The first display element 21 and the second display element 22 are both top light-emitting type display elements, wherein the first display element 21 and the second display element 22 are connected to each other in a back-to-back manner.

A quadrilateral edge portion of the first substrate 211 and a quadrilateral edge portion of the second substrate 221 are completely inserted into a sealing portion 25, so that the first substrate 211 and the second substrate 221 are fixedly connected by the sealing portion 25. Therefore, such a structure can not only fix the first display element 21 and the second display element 22 to each other, but can also simultaneously fix and connect the first display element 21 and the second display element 22 with the corresponding sealing layers.

The first display element 21 and the second display element 22 are combined into one piece which is entirely sealed and packaged by the first sealing layer 23 and the second sealing layer 24; and the quadrilateral edge portion of the first sealing layer 23 and the quadrilateral edge portion of the second sealing layer 24 are sealed and fixed by the sealing portion 25.

Each of the first sealing layer 23 and the second sealing layer 24 is preferably an outer cover with a stronger structure. For further improving the strength of the package structure of this preferred embodiment, the sealing portion 25 can be a sealant layer or a sealing plastic frame.

An advantage of this preferred embodiment is that: compared with the first preferred embodiment, in the preferred embodiment, by the first substrate 211 and the second substrate 221 being inserted into the sealing portion 25, such a structure can not only fix the first display element 21 and the second display element 22 to each other, but can also simultaneously fix and connect the first display element 21 and the second display element 22 with the corresponding sealing layers. At the same time, OLED device layers which are in the first display element 21 and the second display element 22, and cutting edges and wire widths which are between the each corresponding first substrate 211 and second substrate 221, are all located inside the sealing portion 25, so that it can simultaneously seal the entire of two display surfaces, so as to reduce the width of edge frame of the display device, to be a narrow-framed display.

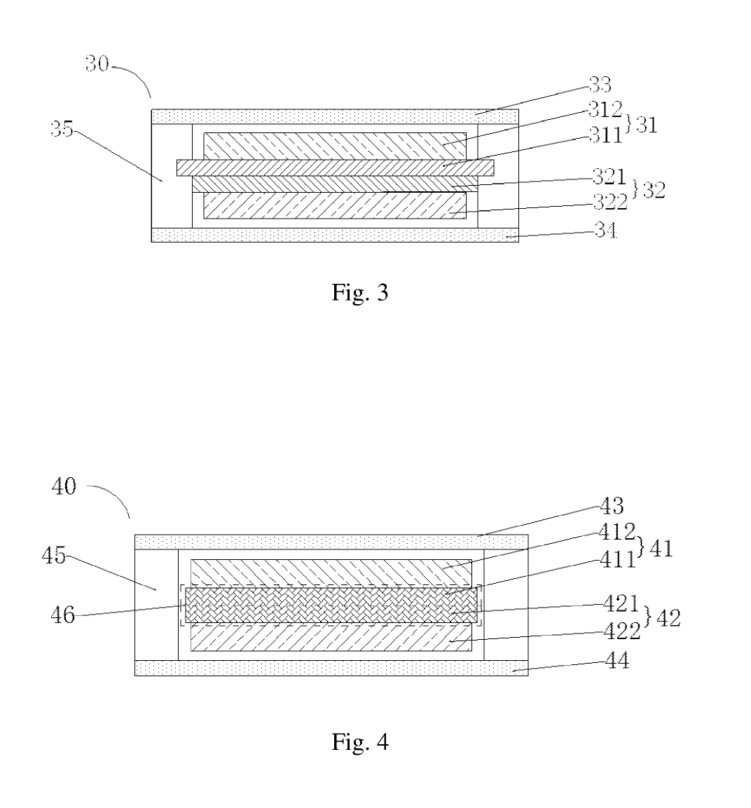

Refer now to FIG. 3, which is a schematic structural view of a double-sided OLED display device according to a third preferred embodiment of the present invention. The double-sided OLED display device 30 comprises a first display element 31, a second display element 32, a first sealing layer 33, and a second sealing layer 34.

The first display element 31 is disposed on an upper side of the second display element 32, and a light-emitting direction of the first display element 31 is opposite to that of the second display element 32; the first sealing layer 33 is disposed on an upper side of the first display element 31, and the second sealing layer 34 is disposed on a lower side of the second display element 32; the first display element 31 includes a first substrate 311 and a first light-emitting portion 312 formed on the first substrate 311; and the second display element 32 includes a second substrate 321 and a second light-emitting portion 322 formed on the second substrate 321.

The first display element 31 and the second display element 32 are both top light-emitting type display elements, wherein the first display element 31 and the second display element 32 are connected to each other in a back-to-back manner.

The first display element 31 and the second display element 32 are combined into one piece which is entirely sealed and packaged by the first sealing layer 33 and the second sealing layer 34; and the quadrilateral edge portion of the first sealing layer 33 and the quadrilateral edge portion of the second sealing layer 34 are sealed and fixed by the sealing portion 35.

Compared with the second preferred embodiment, in this preferred embodiment, a quadrilateral edge portion of the first substrate 311 and a quadrilateral edge portion of the second substrate 321 are only partially inserted into the sealing portion 35, wherein left and right side edge portions of the first substrate 311 are partially inserted into the sealing portion 35, and front and rear side edge portions of the second substrate 321 are partially inserted into the sealing portion 35. That is, an insert-extending direction of the first substrate 311 is perpendicular to that of the second substrate 321.

Each of the first sealing layer 33 and the second sealing layer 34 is preferably an outer cover with a stronger structure. For further improving the strength of the package structure of this preferred embodiment, the sealing portion 35 can be a sealant layer or a sealing plastic frame.

An advantage of this preferred embodiment is that: compared with the second preferred embodiment, in this preferred embodiment, by the first substrate 311 and the second substrate 321 being only partially inserted into the sealing portion 35, complementing to each other, the first substrate 311 and the second substrate 321 are stably fixed, and the material of the first substrate 311 and the second substrate 321 can be saved, so as to lower the cost.

Refer now to FIG. 4, which is a schematic structural view of a double-sided OLED display device according to a fourth preferred embodiment of the present invention. The double-sided OLED display device 40 comprises a first display element 41, a second display element 42, a first sealing layer 43, and a second sealing layer 44.

The first display element 41 is disposed on an upper side of the second display element 42, and a light-emitting direction of the first display element 41 is opposite to that of the second display element 42; the first sealing layer 43 is disposed on an upper side of the first display element 41, and the second sealing layer 44 is disposed on a lower side of the second display element 42; the first display element 41 includes a first substrate 411 and a first light-emitting portion 412 formed on the first substrate 411; and the second display element 42 includes a second substrate 421 and a second light-emitting portion 422 formed on the second substrate 421.

The first display element 41 and the second display element 42 are both top light-emitting type display elements, wherein the first display element 41 and the second display element 42 are connected to each other in a back-to-back manner.

The first display element 41 and the second display element 42 are combined into one piece which is entirely sealed and packaged by the first sealing layer 43 and the second sealing layer 44; and the quadrilateral edge portion of the first sealing layer 43 and the quadrilateral edge portion of the second sealing layer 44 are sealed and fixed by the sealing portion 35.

Compared with the first preferred embodiment, in this preferred embodiment, the first substrate 411 and the second substrate 421 are combined into one piece as a substrate 46, namely, the first display element 41 and the second display element 42 share the substrate 46, wherein the first light-emitting portion 412 is disposed on a top surface of the substrate 46, and the second light-emitting portion 422 is disposed on a bottom surface of the substrate 46.

Each of the first sealing layer 43 and the second sealing layer 44 is preferably an outer cover with a stronger structure. For further improving the strength of the package structure of this preferred embodiment, the sealing portion 45 can be a sealant layer or a sealing plastic frame.

An advantage of this preferred embodiment is that: compared with the first preferred embodiment, in this preferred embodiment, by the first substrate 411 and the second substrate 421 being combined into one piece, the first display element 41 and the second display element 42 share the substrate 46, so as to integrate the first display element 41 and the second display element 42 to simply the package structure.

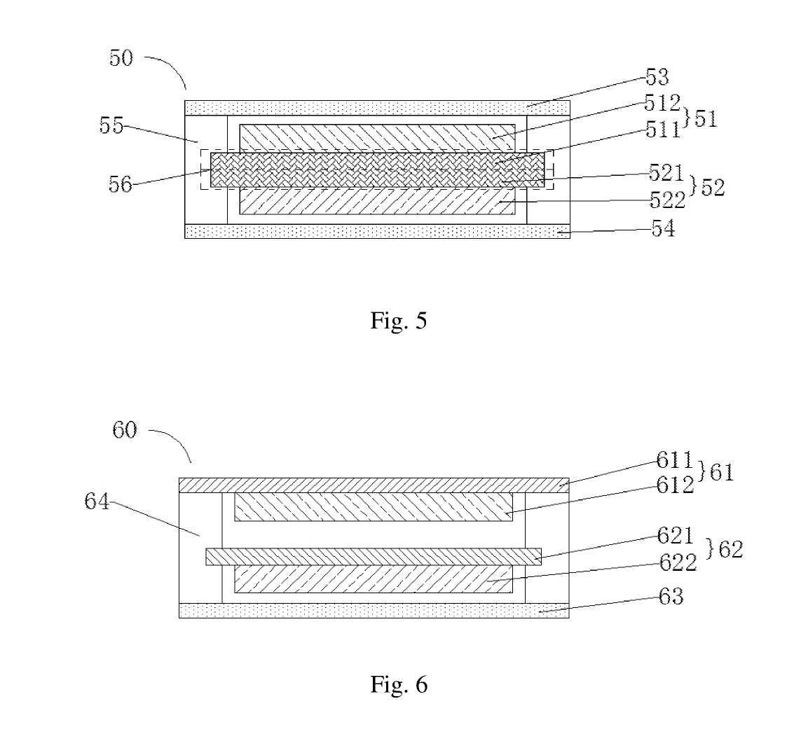

Refer now to FIG. 5, which is a schematic structural view of a double-sided OLED display device according to a fifth preferred embodiment of the present invention. The double-sided OLED display device 50 comprises a first display element 51, a second display element 52, a first sealing layer 53, and a second sealing layer 54.

Compared with the fourth preferred embodiment, in this preferred embodiment, a quadrilateral edge portion of the integrated substrate 56 is inserted into the sealing portion 55.

An advantage of this preferred embodiment is that: compared with the fourth preferred embodiment, in this preferred embodiment, the quadrilateral edge portion of the substrate 56 is inserted into the sealing portion 55, so that such a structure can not only fix the first display element 51 and the second display element 52 to each other, but can also simultaneously fix and connect the first display element 51 and the second display element 52 with the corresponding sealing layers. Thus, the integration of the first display element 51 and the second display element 52 is more stable, and the strength of the preferred embodiment is increased.

Refer now to FIG. 6, which is a schematic structural view of a double-sided OLED display device according to a sixth preferred embodiment of the present invention. The double-sided OLED display device 60 comprises a first display element 61, a second display element 62, and a second sealing layer 63.

The first display element 61 is disposed on an upper side of the second display element 62, and a light-emitting direction of the first display element 61 is opposite to that of the second display element 62; the first display element 61 includes a first substrate 611 and a first light-emitting portion 612 formed on the first substrate 411; and the second display element 62 includes a second substrate 621 and a second light-emitting portion 622 formed on the second substrate 621.

The first display element 61 is a bottom light-emitting type display element, and the second display element 62 is a top light-emitting type display element; and the first display element 61 and the second display element 62 face an identical direction.

The first substrate 611 is as a first sealing layer, which is located at an upper end of the first display element 61, and the second sealing layer 63 is disposed on a lower side of the second display element 62. A quadrilateral edge portion of the second substrate 621 is inserted into a sealing portion 64, and is fixedly connected with the first substrate 611 by the sealing portion 64.

The first display element 61 and the second display element 62 are combined into one piece which is entirely sealed and packaged by the first substrate 611 and the second sealing layer 63. Additionally, by the sealing portion 64, a quadrilateral edge portion of the first substrate 611 and a quadrilateral edge portion of the second sealing layer 63 are sealed and fixed.

The second sealing layer 63 is preferably an outer cover with a stronger structure. For further improving the strength of the package structure of this preferred embodiment, the sealing portion 64 can be a sealant layer or a sealing plastic frame.

An advantage of this preferred embodiment is that: in the preferred embodiment, by using the first substrate 611 to be a first sealing layer, it can save a material of one sealing layer, so as to lower the cost of the preferred embodiment.

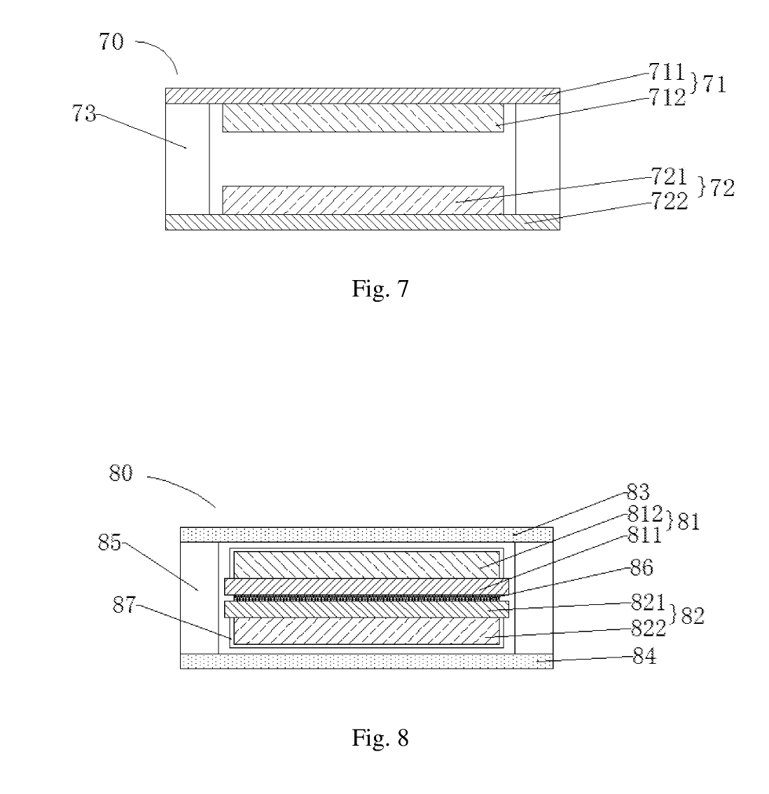

Refer now to FIG. 7, which is a schematic structural view of a double-sided OLED display device according to a seventh preferred embodiment of the present invention. The double-sided OLED display device 70 comprises a first display element 71 and a second display element 72.

The first display element 71 is disposed on an upper side of the second display element 72, and a light-emitting direction of the first display element 71 is opposite to that of the second display element 72; the first display element 71 includes a first substrate 711 and a first light-emitting portion 712 formed on the first substrate 711; and the second display element 72 includes a second substrate 722 and a second light-emitting portion 721 formed on the second substrate 722.

The first display element 71 and the second display element 72 are both bottom light-emitting type display elements; and the first display element 71 and the second display element 72 are opposite to each other in a face-to-face manner.

The first substrate 711 is as a first sealing layer, which is located at an upper end of the first display element 71; and the second substrate 722 is as a second sealing layer, which is located at a lower end of the second display element 72.

The first display element 71 and the second display element 72 are combined into one piece which is entirely sealed and packaged by the first substrate 711 and the second substrate 722. Additionally, by the sealing portion 73, a quadrilateral edge portion of the first substrate 711 and a quadrilateral edge portion of the second substrate 722 are sealed and fixed.

For further improving the strength of the package structure of this preferred embodiment, the sealing portion 73 can be a sealant layer or a sealing plastic frame.

An advantage of this preferred embodiment is that: compared with the sixth preferred embodiment, in this preferred embodiment, by using the first substrate 711 and the second substrate 722 to be sealing layers, it can save a material of sealing layers, so as to lower the cost of the preferred embodiment.

Refer now to FIG. 8, which is a schematic structural view of a double-sided OLED display device according to an eighth preferred embodiment of the present invention. The double-sided OLED display device 80 comprises a first display element 81, a second display element 82, a first sealing layer 83, and a second sealing layer 84.

The first display element 81 is disposed on an upper side of the second display element 82, and a light-emitting direction of the first display element 81 is opposite to that of the second display element 82; the first sealing layer 83 is disposed on an upper side of the first display element 81, and the second sealing layer 84 is disposed on a lower side of the second display element 82; the first display element 81 includes a first substrate 811 and a first light-emitting portion 812 formed on the first substrate 811; and the second display element 82 includes a second substrate 821 and a second light-emitting portion 822 formed on the second substrate 821.

The first display element 81 and the second display element 82 are both top light-emitting type display elements, wherein the first display element 81 and the second display element 82 are connected to each other in a back-to-back manner.

A bottom of the first substrate 811 and a bottom of the second substrate 821 are fixedly connected by a glue layer 86. The first display element 81 and the second display element 82 are combined into one piece which is entirely sealed and packaged by the first sealing layer 83 and the second sealing layer 84. Additionally, by a sealing portion 85, a quadrilateral edge portion of the first sealing layer 83 and a quadrilateral edge portion of the second sealing layer 84 are sealed and fixed.

Compared with the first preferred embodiment, for increasing moisture proofing for the first light-emitting portion 812 and the second light-emitting portion 822, in this preferred embodiment, each of an outer surface of the first light-emitting portion 812 and the second light-emitting portion 822 is covered with a thin-film sealing layer 87, so as to increase a function of separating moisture/oxygen.

It can be understood that covering the thin-film sealing layer 87 to the outer surfaces of the light-emitting portions of the display elements is not only suitable for the top light-emitting type display elements, but also suitable for the bottom light-emitting type display elements.

Additionally, regarding the material of the thin-film sealing layer 87, it can be selected from silicon nitride, silica, or aluminum oxide. Furthermore, the thin-film sealing layer 87 is not limited in one single layer, namely, it can be composed by a plurality of thin-film layers. For example, it is composed by a silicon nitride thin-film and a silica thin-film; by a silicon nitride thin-film and an aluminum oxide thin-film; or by a silicon nitride thin-film, a silica thin-film and an aluminum oxide thin-film. Here, it is possible to add an appropriate organic material into the thin-film sealing layer 87.

Increasing the function of separating moisture/oxygen can also be accomplished by other executing methods. For example, putting a drying agent into the two sealing layers.

The packaging operation of this preferred embodiment is similar to or the same as that of the first preferred embodiment, so please refer the packaging operation of the first preferred embodiment.

Compared with the above-mentioned preferred embodiment, in the preferred embodiment, by disposing the thin-film sealing layer, moisture proofing is increased, so as to protect the light-emitting portions, and the lifetime of the preferred embodiment is lengthened.

The present invention has been described with preferred embodiments thereof and it is understood that many changes and modifications to the described embodiment can be carried out without departing from the scope and the spirit of the invention that is intended to be limited only by the appended claims.

What is claimed is:

1. A double-sided OLED display device, comprising: a first display element, a second display element, a first sealing layer, and a second sealing layer, wherein the first display element is disposed on an upper side of the second display element, and a light-emitting direction of the first display element is opposite to that of the second display element; the first sealing layer is disposed on an upper side of the first display element, and the second sealing layer is disposed on a lower side of the second display element;
wherein the first display element and the second display element are combined into one piece which is entirely sealed and packaged by the first sealing layer and the second sealing layer; and the first sealing layer and the second sealing layer are sealed and fixed by a sealing portion;
wherein the sealing portion is a sealing plastic frame or a sealant layer;
wherein each of the first light-emitting portion and the second light-emitting portion includes a light-emitting layer, a positive electrode, an organic functional layer, and a negative electrode; and
wherein the light-emitting layer is disposed between the positive electrode and the organic functional layer, and the organic functional layer is disposed between the light-emitting layer and the negative electrode.

2. The double-sided OLED display device according to claim 1, wherein each of the first display element and the second display element is a top light-emitting type display element, while the first display element and the second display element are connected to each other in a back-to-back manner;
wherein the first display element includes a first substrate and a first light-emitting portion formed on the first substrate; and the second display element includes a second substrate and a second light-emitting portion formed on the second substrate; and
wherein a bottom of the first substrate and a bottom of the second substrate are fixedly connected by a glue layer; and a quadrilateral edge portion of the first sealing layer is sealed and fixed to a quadrilateral edge portion of the second sealing layer by the sealing portion.

3. The double-sided OLED display device according to claim 1, wherein each of the first display element and the second display element is a top light-emitting type display elements, while the first display element and the second display element are connected to each other in a back-to-back manner;
wherein the first display element includes a first substrate and a first light-emitting portion formed on the first substrate; and the second display element includes a second substrate and a second light-emitting portion formed on the second substrate; and
wherein a quadrilateral edge portion of the first substrate is completely or partially inserted into the sealing portion; a quadrilateral edge portion of the second substrate is completely or partially inserted into the sealing portion; the first substrate and the second substrate are fixedly connected by the sealing portion; and a quadrilateral edge portion of the first sealing layer is sealed and fixed to a quadrilateral edge portion of the second sealing layer by the sealing portion.

4. The double-sided OLED display device according to claim 1, wherein each of the first display element and the second display element is a top light-emitting type display elements, while the first display element and the second display element are connected to each other in a back-to-back manner;
wherein the first display element and the second display element share a substrate; the first display element further includes a first light-emitting portion formed on the substrate; and the second display element further includes a second light-emitting portion formed on the substrate; and
wherein the first light-emitting portion is disposed on a top surface of the substrate, and the second light-emitting portion is disposed on a bottom surface of the substrate; and a quadrilateral edge portion of the first sealing layer are sealed and fixed to a quadrilateral edge portion of the second sealing layer by the sealing portion.

5. The double-sided OLED display device according to claim 4, wherein the substrate is inserted into the sealing portion.

6. The double-sided OLED display device according to claim 1, wherein the first display element is a bottom light-emitting type display element, and the second display element is a top light-emitting type display element;
and the first display element and the second display element face an identical direction;
wherein the first display element includes a first substrate and a first light-emitting portion formed on the first substrate; and the second display element includes a second substrate and a second light-emitting portion formed on the second substrate; and
wherein the first sealing layer is the first substrate; a quadrilateral edge portion of the second substrate is partially inserted into the sealing portion, and the second substrate is fixedly connected to the first substrate by the sealing portion; and a quadrilateral edge portion of the first sealing layer is sealed and fixed to a quadrilateral edge portion of the second sealing layer by the sealing portion.

7. The double-sided OLED display device according to claim 1, wherein each of the first display element and the second display element is a bottom light-emitting type display elements, while the first display element and the second display element are opposite to each other in a face-to-face manner;
wherein the first display element includes a first substrate and a first light-emitting portion formed on the first substrate; and the second display element includes a second substrate and a second light-emitting portion formed on the second substrate; and
wherein the first sealing layer is the first substrate, and the second sealing layer is the second substrate; and a quadrilateral edge portion of the first substrate is sealed and fixed to a quadrilateral edge portion of the second substrate by the sealing portion.

8. The double-sided OLED display device according to claim 1, wherein each of an outer surface of the first light-emitting portion and an outer surface of the second light-emitting portion is covered with a thin-film sealing layer.

9. A double-sided OLED display device, comprising: a first display element, a second display element, a first sealing layer, and a second sealing layer,
wherein the first display element is disposed on an upper side of the second display element, and a light-emitting direction of the first display element is opposite to that of the second display element; the first sealing layer is disposed on an upper side of the first display element, and the second sealing layer is disposed on a lower side of the second display element;
wherein the first display element and the second display element are combined into one piece which is entirely sealed and packaged by the first sealing layer and the second sealing layer; and the first sealing layer and the second sealing layer are sealed and fixed by a sealing portion.

10. The double-sided OLED display device according to claim 9, wherein each of the first display element and the second display element is a top light-emitting type display element, while the first display element and the second display element are connected to each other in a back-to-back manner;
wherein the first display element includes a first substrate and a first light-emitting portion formed on the first substrate; and the second display element includes a second substrate and a second light-emitting portion formed on the second substrate; and
wherein a bottom of the first substrate and a bottom of the second substrate are fixedly connected by a glue layer; and a quadrilateral edge portion of the first sealing layer is sealed and fixed to a quadrilateral edge portion of the second sealing layer by the sealing portion.

11. The double-sided OLED display device according to claim 9, wherein each of the first display element and the second display element is a top light-emitting type display elements, while the first display element and the second display element are connected to each other in a back-to-back manner;
wherein the first display element includes a first substrate and a first light-emitting portion formed on the first substrate; and the second display element includes a second substrate and a second light-emitting portion formed on the second substrate; and
wherein a quadrilateral edge portion of the first substrate is completely or partially inserted into the sealing portion; a quadrilateral edge portion of the second substrate is completely or partially inserted into the sealing portion; the first substrate and the second substrate are fixedly connected by the sealing portion; and a quadrilateral edge portion of the first sealing layer is sealed and fixed to a quadrilateral edge portion of the second sealing layer by the sealing portion.

12. The double-sided OLED display device according to claim 9, wherein each of the first display element and the second display element is a top light-emitting type display elements, while the first display element and the second display element are connected to each other in a back-to-back manner;
wherein the first display element and the second display element share a substrate; the first display element further includes a first light-emitting portion formed on the substrate; and the second display element further includes a second light-emitting portion formed on the substrate; and
wherein the first light-emitting portion is disposed on a top surface of the substrate, and the second light-emitting portion is disposed on a bottom surface of the substrate; and a quadrilateral edge portion of the first sealing layer is sealed and fixed to a quadrilateral edge portion of the second sealing layer by the sealing portion.

13. The double-sided OLED display device according to claim 12, wherein the substrate is inserted into the sealing portion.

14. The double-sided OLED display device according to claim 9, wherein the first display element is a bottom light-emitting type display element, and the second display element is a top light-emitting type display element;
and the first display element and the second display element face an identical direction;
wherein the first display element includes a first substrate and a first light-emitting portion formed on the first substrate; and the second display element includes a second substrate and a second light-emitting portion formed on the second substrate; and
wherein the first sealing layer is the first substrate; a quadrilateral edge portion of the second substrate are partially inserted into the sealing portion, and the second substrate are fixedly connected to the first substrate by the sealing portion; and a quadrilateral edge portion of the first sealing layer are sealed and fixed to a quadrilateral edge portion of the second sealing layer by the sealing portion.

15. The double-sided OLED display device according to claim 9, wherein each of the first display element and the second display element is a bottom light-emitting type display elements, while the first display element and the second display element are opposite to each other in a face-to-face manner;
wherein the first display element includes a first substrate and a first light-emitting portion formed on the first substrate; and the second display element includes a second substrate and a second light-emitting portion formed on the second substrate; and
wherein the first sealing layer is the first substrate, and the second sealing layer is the second substrate; and a quadrilateral edge portion of the first substrate is sealed and fixed to a quadrilateral edge portion of the second substrate by the sealing portion.

16. The double-sided OLED display device according to claim 9, wherein each of an outer surface of the first light-emitting portion and an outer surface of the second light-emitting portion is covered with a thin-film sealing layer.

17. The double-sided OLED display device according to claim 9, wherein the sealing portion is a sealing plastic frame or a sealant layer.

18. The double-sided OLED display device according to claim 9, wherein each of the first light-emitting portion and the second light-emitting portion includes a light-emitting layer, a positive electrode, an organic functional layer, and a negative electrode; and
wherein the light-emitting layer is disposed between the positive electrode and the organic functional layer, and the organic functional layer is disposed between the light-emitting layer and the negative electrode.
